(19) United States
(12) Patent Application Publication
(10) Pub. No.: US 2012/0168577 A1
(43) Pub. Date: Jul. 5, 2012

(54) SHELL FOR ELECTRONIC DEVICE

(75) Inventor: QUAN-CHANG CHENG, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/213,070

(22) Filed: Aug. 18, 2011

(30) Foreign Application Priority Data
Dec. 29, 2010 (CN) 201010612744.0

(51) Int. Cl. H05K 7/00

(52) U.S. Cl. 248/176.3

(57) ABSTRACT

A shell includes a main body, a first supporting member and a second supporting member. The first supporting member is pivotally coupled to and foldable on the main body. The second supporting member is pivotally coupled to and foldable on the first supporting member. When the first supporting member is rotated to keep an angle with the main body, the first supporting member is capable of supporting the main body in a first orientation and in a second orientation different from the first orientation. When the first supporting member is folded on the main body and the second supporting member is rotated to keep an angle with the main body, the second supporting member is capable of supporting the main body in the first orientation and in the second orientation.

### BACKGROUND

1. Technical Field

The present disclosure relates to a shell for a device.

2. Description of Related Art

Hand-held electronic devices, such as PDAs, MP3s, and mobile phones, are widely used in people's daily life. However, many of the hand-held devices do not have a supporting mechanism if a user wants to set their device down on a supporting surface, such as a table, and watch movies or read e-books, which is inconvenient.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the eight views.

FIG. 1 is a perspective view of a shell for supporting an electronic device in accordance with an embodiment.

FIG. 2 is similar to FIG. 1, but viewed from another aspect.

FIG. 3 is a disassembled view of the shell of FIG. 1; the shell includes a first supporting member and a second supporting member.

FIG. 4 is an explanatory view showing the electronic device of FIG. 2 being supporting in a first orientation by the first supporting member.

FIG. 5 is an explanatory view showing the electronic device of FIG. 2 being supporting in the first orientation by the first supporting member cooperating with the second supporting member.

FIG. 6 is an explanatory view showing the electronic device of FIG. 2 being supporting in a second orientation by the first supporting member.

FIG. 7 is an explanatory view showing the electronic device of FIG. 2 being supporting in the first orientation by the second supporting member.

FIG. 8 is an explanatory view showing the electronic device of FIG. 2 being supporting in the second orientation by the second supporting member

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

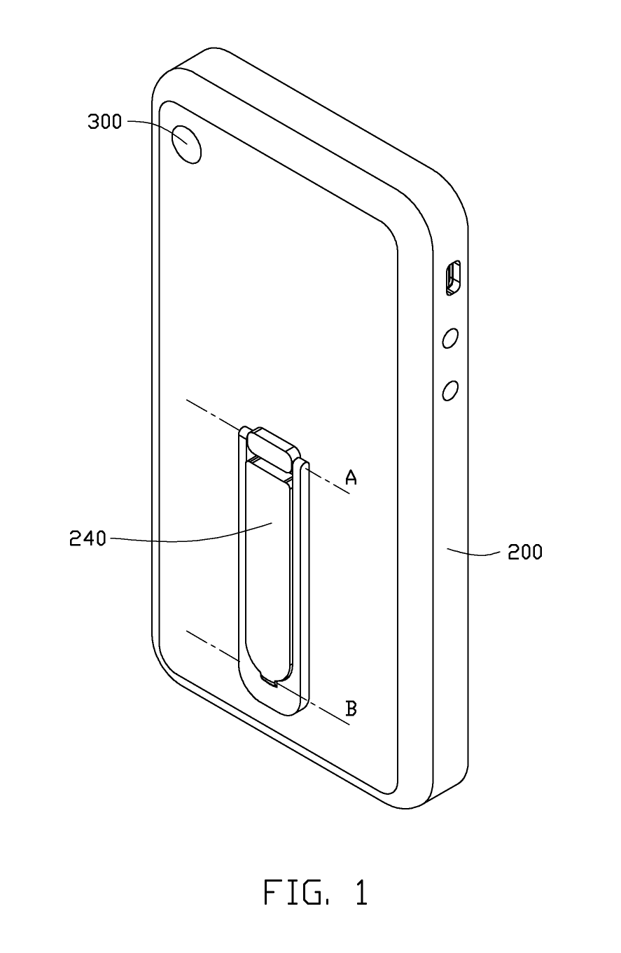

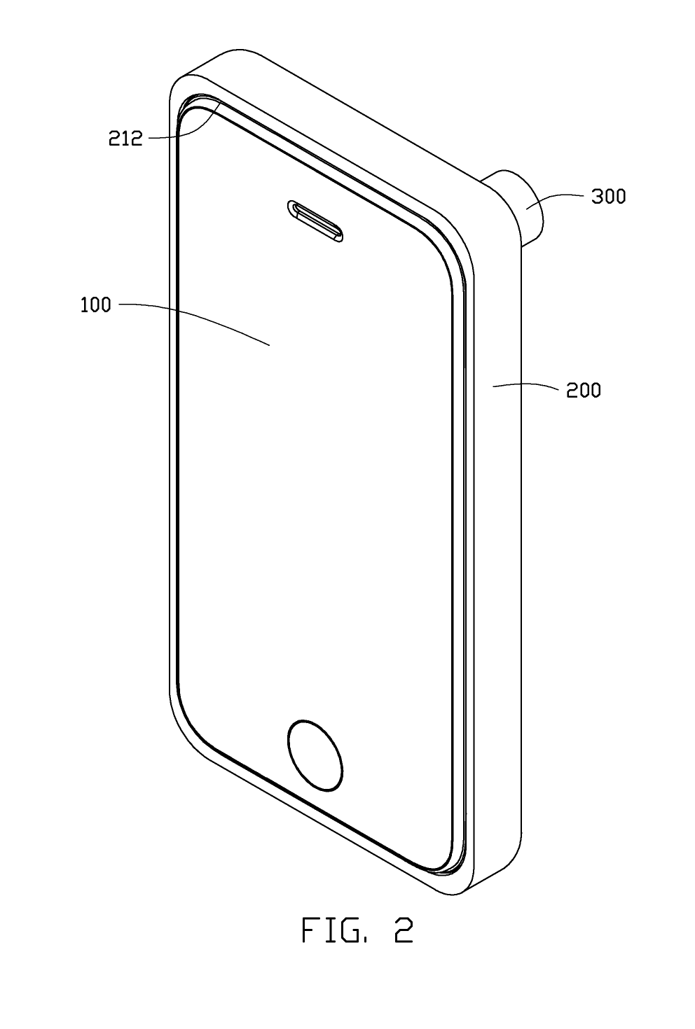

Referring to FIGS. 1 and 2, a shell 200 for supporting an electronic device 100 in accordance with an embodiment is shown. The electronic device 100 may be a cellular phone, a personal digital assistant (PDA), a media player or the like. The shell 200 is capable of supporting the electronic device 100 in different orientations. In the embodiment, the electronic device 100 is a mobile phone having a camera (not shown).

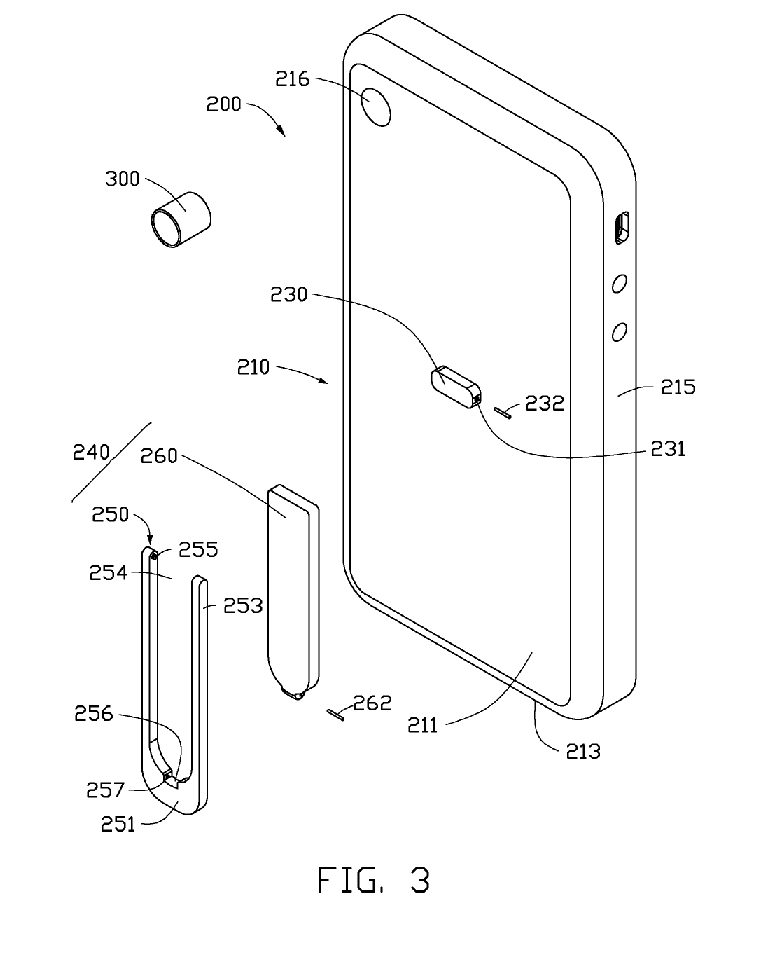

Referring to FIG. 3 also, the shell 200 includes a main body 210, a stand 230, and a supporting mechanism 240. The main body 210 defines a receiving space 212 for housing the electronic device 100 which is bounded on four sides by two opposite first sidewalls 213 and two opposite second sidewalls 215 perpendicular to the first sidewalls 213, and has a back wall 211. The stand 230 is secured to the back wall 211, and defines a through hole 231 for receiving a shaft 232. The supporting mechanism 240 is rotatably coupled to the stand 230, and is used to support the main body 210 in different orientations.

An aperture 216 is defined in a corner of the main body 210 and communicates with the receiving space 212. When the electronic device 100 is received in the receiving space 212, the aperture 216 corresponds to a lens of the camera. The shell 200 can further include an external lens 300 received in the aperture 216. In some embodiments, the external lens 300 can be an adjustable lens able to be focused or usable to perform zooming functions.

The supporting mechanism 240 includes a first supporting member 250 and a second supporting member 260. The first supporting member 250 is rotatably coupled to the stand 230 by the shaft 232, and is rotatable around a first axis A (see FIG. 1), relative to the main body 210. The second supporting member 260 is rotatably coupled to the first supporting member 250, and is rotatable around a second axis B (see FIG. 1), parallel to the first axis A.

The first supporting member 250 includes a base 251 and two arms 253 projecting from the base 251. The two arms 253 are coplanar with the base 251 and cooperate with the base 251 to define a U-shaped receiving portion 254. The receiving portion 254 is used for receiving the second supporting member 260. An end of each arm 253 opposite to the base 251 defines a first shaft hole 255 for rotatably receiving the shaft 232. A side of the base 251 from which the arms 253 projecting defines a cutout 256. Opposite sides of the cutout 256 further defines two second shaft holes 257 for rotatably receiving a shaft rod 262.

The second supporting member 260 is substantially U-shaped. The second supporting member 260 is rotatably coupled to the base 251 by the shaft rod 262 being rotatably received in the second shaft holes 255, and is received in the receiving portion 254.

When the electronic device 100 is to be supported on a surface, such as a table (not shown): the electronic device 100 is firstly received in the receiving space 212 with the lens of the camera corresponding to the external lens 300, and then, the supporting mechanism 240 is operated to adjust the electronic device 100 being supported in different orientations.

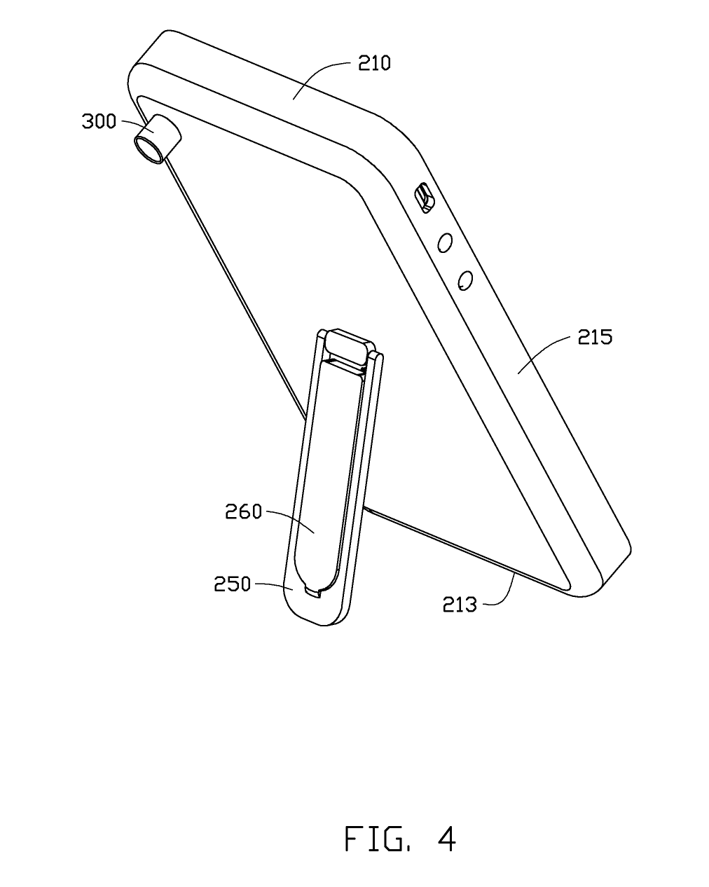

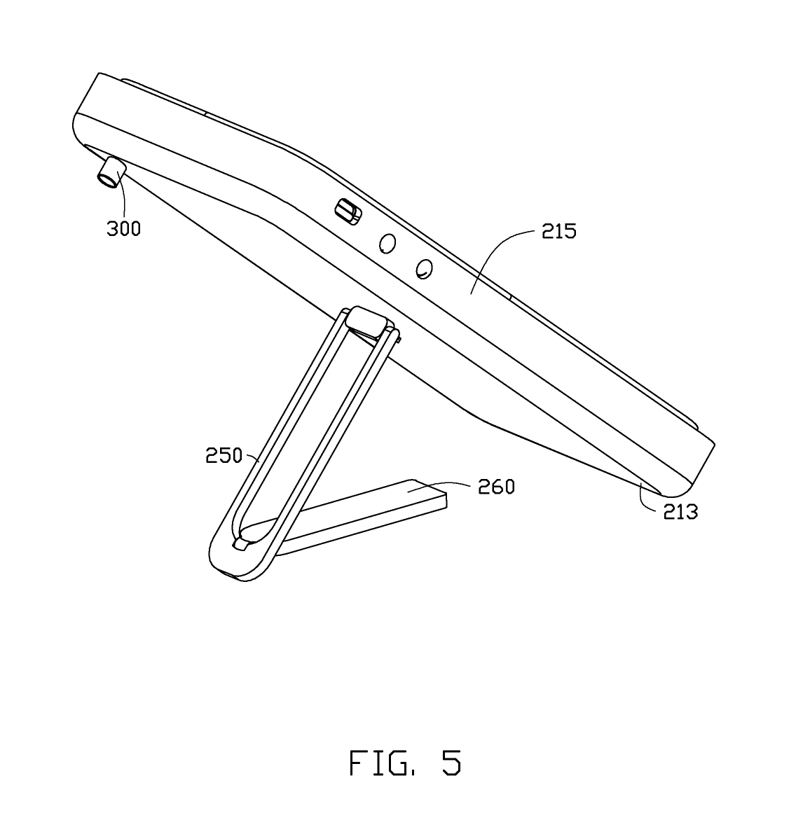

Referring to FIG. 4, when the first supporting arm 250 is rotated to keep an acute angle with the back wall 211, and the second supporting arm 250 stays in the receiving portion 254, the first supporting arm 250 cooperates with one of the first sidewalls 213 to support the electronic device 100 in a first orientation. Referring to FIG. 5, when the shell 200 is supported by the first supporting member 250 in the first orientation, the second supporting member 260 can be unfolded to provide an added supporting point for the shell 200.

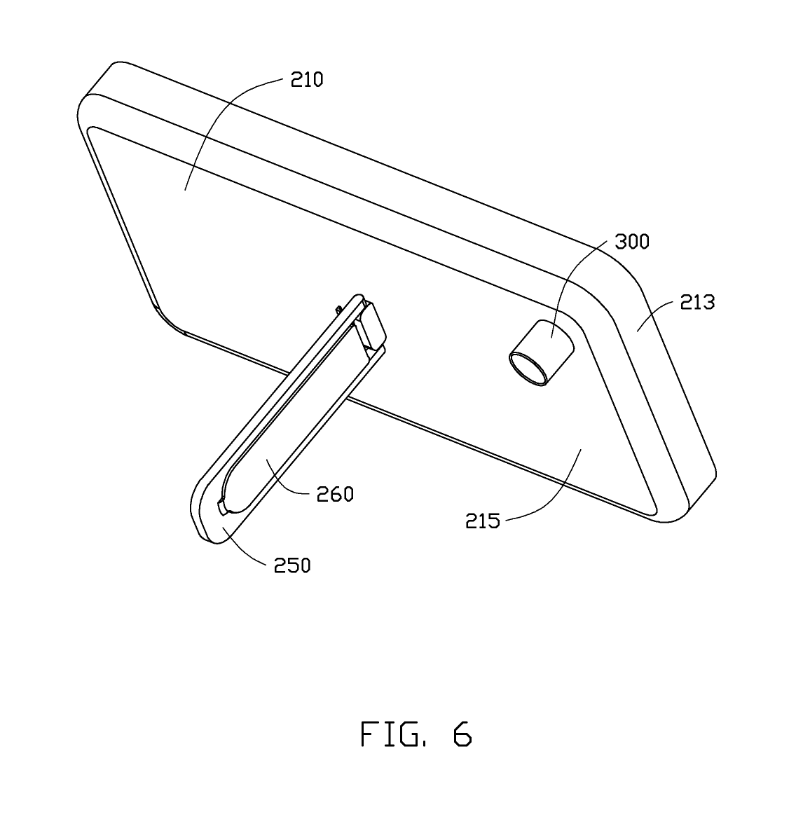

Referring to FIG. 6, when the first supporting arm 250 is rotated to be substantially perpendicular to the back wall 211, the first supporting member 250 cooperates with one of the second sidewalls 215 to support the electronic device 100 in a second orientation.

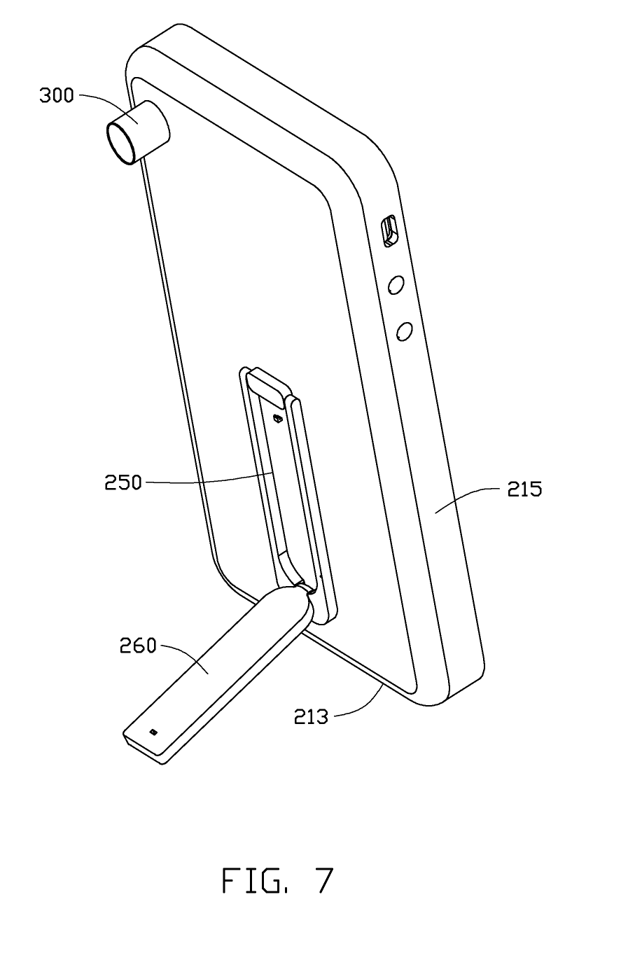

Referring to FIG. 7, the first supporting member 250 is folded on the back wall 211, and the second supporting member 260 is rotated to keep an acute angle with the back wall 211. In this state, the second supporting member 260 cooperates with the first sidewall 213 to support the electronic device 100 in the first orientation.

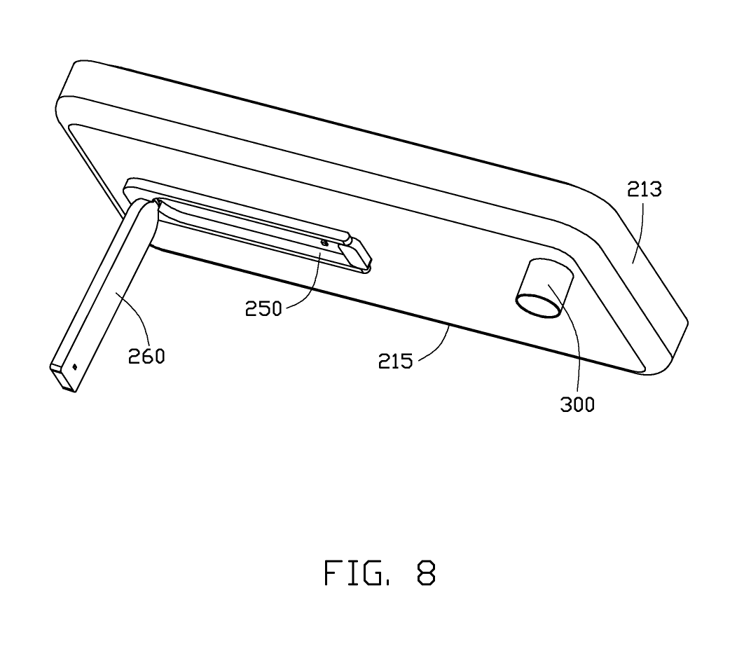

FIG. 8 shows the second supporting arm 260 rotated to be substantially perpendicular to the back wall 211, and the second supporting member 260 cooperating with one of the second sidewalls 215 to support the electronic device 100 in the second orientation.

With assistance of the shell 200, the electronic device 100 is capable of being supported in different orientations, which is convenient.

Even though information and the advantages of the present embodiments have been set forth in the foregoing description, together with details of the structures and functions of the present embodiments, the disclosure is illustrative only; and changes may be made in detail, especially in matters of shape, size, and arrangement of parts within the principles of the present embodiments to the full extent indicated by the broad general meaning of the terms in which the appended claims are expressed.

What is claimed is:

1. A shell for an electronic device, comprising:
a main body defining a receiving space for receiving the electronic device;
a first supporting member pivotally coupled to and foldable on the main body; and
a second supporting member pivotally coupled to and foldable on the first supporting member;
wherein when the first supporting member is rotated to keep an angle with the main body, the first supporting member is capable of supporting the main body in a first orientation and in a second orientation different from the first orientation; when the first supporting member is folded on the main body and the second supporting member is rotated to keep an angle with the main body, the second supporting member is capable of supporting the main body in the first orientation and in the second orientation.

2. The shell of claim 1, wherein the first supporting member comprises a base and two arms projecting from the base, the arms cooperate with the base to define a receiving portion.

3. The shell of claim 2, wherein ends of the arms opposite the base define two first shaft holes, the first supporting member is pivotally coupled to the base via the first shaft holes and is rotatable around a first axis relative to the main body.

4. The shell of claim 3, wherein a sidewall of the base where the arms projecting defines a cutout, two sides of the cutout defines two second shaft holes.

5. The shell of claim 4, wherein the second supporting member is pivotally coupled to the base by the second shaft holes and is received in the receiving portion, the second supporting member is rotatable relative to the first supporting member around a second axis.

6. The shell of claim 5, wherein the second axis is parallel to the first axis.

7. The shell of claim 1, wherein the main body comprises a stand, the first supporting member is pivotally coupled to the stand.

8. A shell, comprising:
a main body comprising a first sidewall and at least one second sidewall connecting with the first sidewall;
a first supporting member rotatably coupled to the main body and rotatable around a first axis; and
a second supporting member rotatably coupled to the first supporting member and rotatable around a second axis parallel to the first axis;
wherein when the first supporting member rotates around the first axis to keep an angle with the main body, the first supporting member cooperates with the first sidewall to support the main body in a first orientation, and cooperates with the at least one second sidewall to support the main body in a second orientation different from the first orientation; and when the second supporting member rotates around the second axis to keep an angle with the main body, the second supporting member cooperates with the first sidewall to support the main body in the first orientation, and cooperates with the at least one second sidewall to support the main body in the second orientation.

9. The shell of claim 8, wherein the first supporting member comprises a base and two arms project from the base, the arms cooperate with the base to define a receiving portion.

10. The shell of claim 9, wherein ends of the arms opposite the base define two first shaft holes, the first supporting member is pivotally coupled to the base via the first shaft holes.

11. The shell of claim 10, wherein a sidewall of the base where the arms projecting defines a cutout, two sides of the cutout defines two second shaft holes.

12. The shell of claim 11, wherein the second supporting member is pivotally coupled to the base by the second shaft holes and is received in the receiving portion.
